(19) United States
(12) Patent Application Publication
(10) Pub. No.: US 2009/0068574 A1
(43) Pub. Date: Mar. 12, 2009

(54) SUBSTRATE WITH BANK, AND SUBSTRATE WITH COLOR PATTERN

(75) Inventors: Kazushige Kitazawa, Tokyo (JP); Hiroyuki Miura, Tokyo (JP); Teruhiko Kai, Tokyo (JP); Hideyuki Yamada, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 11/853,797

(22) Filed: Sep. 11, 2007

(51) Int. Cl. G03F 3/00

(52) U.S. Cl. 430/7

(57) ABSTRACT

An embodiment of the present invention is disclosed. A substrate with a bank, comprising a substrate; and a bank on the substrate, wherein the bank comprises a resin composition containing at least a binder resin, and melamine resin or a derivative thereof, and the amount of the melamine resin or derivative thereof is from 5 to 30 parts by weight relative to 100 parts by weight of the binder resin. Further, colored layers have been formed in pixels sectioned with the banks by printing through an ink-jet system.

### BACKGROUND OF THE INVENTION

1. Field of the Invention

The present invention relates to a substrate with a bank, and a substrate with a color pattern for use in liquid crystal display devices and organic electroluminescence elements or the like. More particularly, the invention relates to a substrate with a color pattern having a flat and uniform colored layer for respective pixels, in a substrate with a color pattern in which respective pixels are printed by an ink-jet system.

2. Description of the Related Art

Color filters for use in color liquid crystal display devices etc. are an indispensable member for color liquid crystal display devices etc., and have such function as improving the image quality of liquid crystal display devices and giving respective pixels respective primary hues. For the production method of the color filters, various studies have been conducted, and, as representative methods, a photolithographic system, an ink-jet system etc. are known. In the photolithographic system, a coated film of a photosensitive resin for respective colors is formed on an entire substrate, and then unnecessary portions of the coated film are removed to leave a pattern for pixels of respective colors. In this method, since many portions of the coated film become unnecessary, a large quantity of such material as pigment is wasted at the production of color filters. Further, since exposure and development steps are carried out for pixels of respective colors, the number of steps increases. Consequently, the production of color filters through the photolithographic system has problems in both cost and environmental point of view. In theses days in particular, a growth in the size of liquid crystal display devices proceeds. Accordingly, the size of a substrate for a color filter also grows and further huge quantities of materials are wasted. For solving the problem, in these years, the ink-jet system attracts attention as a production method of a color filter. The production of a color filter by means of the ink-jet system can be practiced at one time, because each of photosensitive resin compositions for three colors, R, G, B is used as an ink and respective colors are printed at the same time. As the result, almost no such material as pigment is wasted and, simultaneously, the step for forming three color pixels is shortened, therefore reduction in environment load and significant reduction in the cost can be expected.

For a production method of a color filter substrate using the ink-jet system, there are proposed such methods as described in JP-A-6-347637, JP-A-7-35915, JP-A-7-35917, JP-A-7-248413 and JP-A-2002-62422. JP-A-6-347637 describes that, in order to prevent the spread of an ink outside an intended colored layer region on a glass substrate, patterns are formed while previously incorporating a fluorine-containing water-repellent/oil-repellent agent in black bank portions sectioning respective pixels to fix the ink in regions to be colored. JP-A-7-35915 and JP-A-7-35917 describe the use of a black resin layer including a fluorine-containing compound and/or a silicon-containing compound for banks for preventing ink bleeding and color mixture in the formation step of colored layers. JP-A-7-248413 describes such a production method as including a step of forming either the surface of bank portions for respective pixels or the surface of the pixels so as to have water-repelling/oil-repelling properties, and then subjecting the substrate to treatment for losing the water-repelling/oil-repelling properties.

However, in these conventional methods, there is such problem that the colored resin composition printed by means of the ink-jet system (hereinafter, referred to as colored layer) constituted a convex shape, instead of a flat shape. This resulted in the occurrence of variation of the shape of respective pixels in color filters, the occurrence of defect so-called “color void” in portions having a thin layer, and the occurrence of color unevenness due to the difference in chromaticity, to cause the poor quality of color liquid crystal display devices produced by using such color filters. Consequently, there is proposed a method in which bank portions are formed in a quadrangular shape or an inversely tapered shape to make colored layers flat (JP-A-2002-62422, JP-A-2004-245972). However, in conventional bank portions having been formed by using such resin composition as thermosetting resin, there occurred such phenomenon that corners partook of roundness (hereinafter, referred to as “heat sagging”) in a thermosetting step (at around 150° C. to 250° C.). The heat sagging appeared more conspicuously when the temperature of the thermosetting step was higher, or the thickness of the bank portion was larger. On the other hand, when the bank portion was heat-treated at low temperatures less than 150° C. in order to prevent the heat sagging, the resin of the bank portion was not hardened sufficiently, therefore there occurred such problem that the resin of the bank portion dissolved in the colored ink of an ink-jet. JP-A-2002-62422 and JP-A-2004-245972 do not disclose a method for solving the problem. Therefore, in a color filter produced by means of the ink-jet system, it is still difficult to obtain bank portions in quadrangular or inversely tapered shape without generating the problem of the heat sagging and dissolution.

The invention was achieved in order to solve the above problem, and aims, in a method for producing a color filter (a substrate with a color pattern) by means of an ink-jet system, to provide bank portions having an ideal quadrangle or inversely tapered shape with no occurrence of deformation of thermosetting resin of the bank portion due to the heat sagging, and, thereby, to provide a method for producing a color filter (a substrate with a color pattern) in which colored compositions in respective pixels are flat and no color unevenness exists.

### SUMMARY OF THE INVENTION

An embodiment of the present invention is a substrate with a bank, comprising a substrate; and a bank on the substrate, wherein the bank comprises a resin composition containing at least a binder resin, and melamine resin or a derivative thereof, and the amount of the melamine resin or derivative thereof is from 5 to 30 parts by weight relative to 100 parts by weight of the binder resin. Further, colored layers have been formed in pixels sectioned with the banks by printing through an ink-jet system.

### BRIEF DESCRIPTION OF THE DRAWINGS

FIG. 1 is an illustrative drawing of the cross-sectional shape of a substrate with a color pattern provided with the bank of one embodiment of the present invention.

FIG. 2 is an illustrative drawing of the cross-sectional shape of a substrate with a color pattern provided with the bank of the present invention.

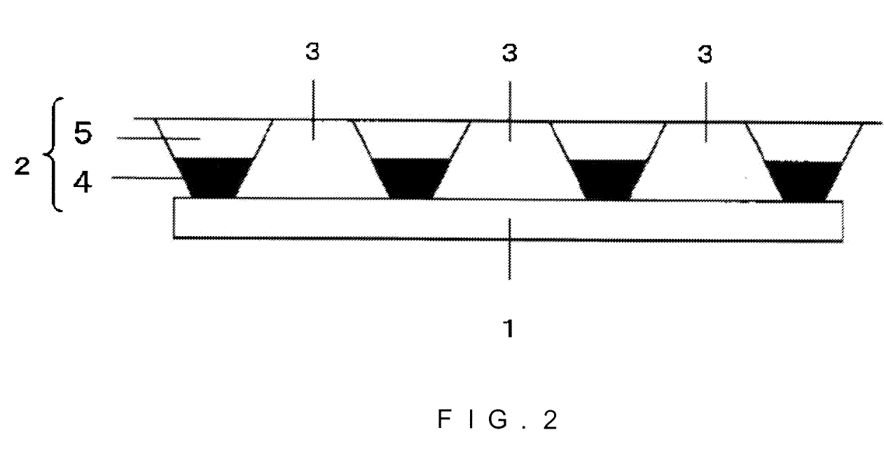

### DESCRIPTION OF SYMBOLS

1: transparent substrate
2: bank portion (black matrix)
3: colored layer
4: light-shielding portion
5: non-shielding portion

### DESCRIPTION OF THE PREFERRED EMBODIMENTS

According to examinations of the present inventor, by using a binder resin and a melamine derivative capable of cross linking reaction with the binder resin for the bank portions and subjecting the same to thermosetting at low temperatures, bank portions having a good shape with no occurrence of heat sagging were obtained. Further, the bank portions did not dissolve in a colored ink. Therefore, colored compositions in respective pixels formed through an ink-jet system became flat, to make it possible to give a substrate with a color pattern with high resolution having good properties free of color unevenness.

In the production method used for the invention, when forming the bank portions with a thickness of 1.5 μm or more, the bank portions did not generate heat sagging, and had tetragonal or inversely tapered shape. Then, on the transparent substrate having the bank portions with a thickness of 1.5 μm or more, colored layers were printed by means of an ink-jet system to give a substrate with a color pattern with flat colored layers. Further, it was found that the effect on preventing color mixture was more improved compared with a substrate with a color pattern having bank portions with a thickness of less than 1.5 μm.

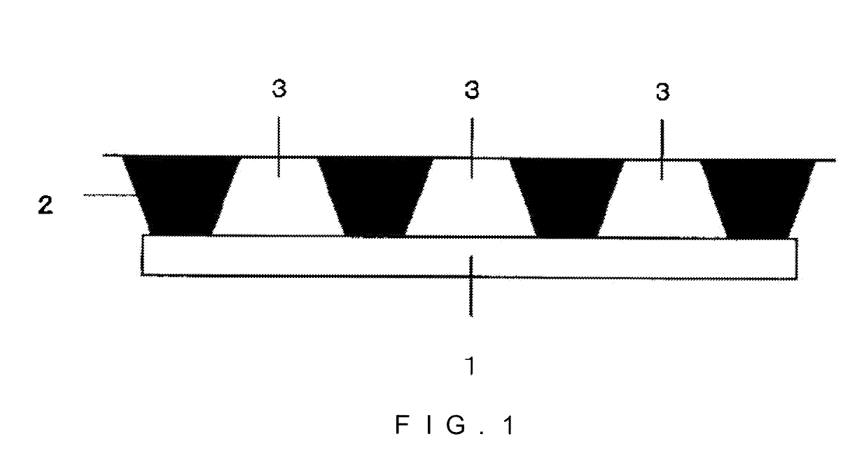

As shown in FIG. 1, in a substrate with a color pattern to be produced by forming colored layers by means of an ink-jet system, the bank portions are provided on a transparent substrate 1 for the purpose of preventing color mixture of colored inks of red (R), green (G) and blue (B). Further, in order to improve the contrast of a substrate with a color pattern, it is desired to give light-shielding properties to a part or the whole of bank portions 2. A bank having light-shielding property can be used as, so-called, a black matrix. In general, for a means for giving light-shielding properties, a black material is used for a part or the whole of the bank portions to provide a black portion. Then, on the transparent substrate, colored layers of red (R), green (G) and blue (B) are formed. In case where it is used for liquid crystal display devices, a transparent electroconductive layer and an alignment layer are sequentially laminated. By opposing it to a facing substrate on which such electrode as a thin film transistor has been formed, and via a liquid crystal layer, a liquid crystal display device is constituted. Hereinafter, a component composed of a transparent substrate, the bank and colored pixel layers of red, green and blue is defined as a substrate with a color pattern. On the substrate with a color pattern, a protective layer 4 may be provided according to need.

As described above, colored layers are provided in openings surrounded by the bank, and, usually, a pixel pattern composed of three primary colors, that is, a red pixel pattern (R), a green pixel pattern (G), and a blue pixel pattern (B) is arranged in an intended shape. For a general production method thereof, there can be mentioned a pigment dispersion method, a dye method, an electrodeposition method, a printing method, a transfer method, and an ink-jet system. In the invention, colored resin compositions are patterned with an ink-jet apparatus, and then, via a heating step as described later, a colored layer 3 is formed.

For the transparent substrate 1 of a substrate with a color pattern, such publicly known transparent substrate material as a glass substrate, a quartz substrate, or a plastic substrate can be employed. Among these, a glass substrate is excellent in transparency, strength, heat resistance, and weather resistance.

For the colored resin composition for use in the colored layer 3 of the substrate with a color pattern, such publicly known materials as a colorant, a thermosetting resin and a solvent can be employed, and it can be prepared by adding such additive as a dispersant according to need.

The usage of a color pigment for a color filter as a colorant can allow a substrate with a color pattern to be used as a color filter. In addition, the usage of a light emitting material as a colorant can allow a substrate with a color pattern to be used as an electroluminescence element.

In addition, a color filter can be used for not only a liquid crystal display but also an electroluminescence element of white color.

Hereinafter, the formation of the bank is detailed. The bank can be formed in a pattern through either of a printing method and a photolithographic system. When forming the bank through a printing method, the pattern of the bank can be printed by using a printing material including a binder resin and a melamine resin. When forming the bank through a photolithographic system, there are two cases, that is, a case where a negative type photosensitive resin composition is used, and a case where a positive type photosensitive resin composition is used. In the former negative type case, it is possible to form a bank pattern by coating a negative type photosensitive resin material including a binder resin, a melamine resin and a photopolymerization initiator capable of initiating radical polymerization on the substrate 1, and then exposing the same via a mask and patterning it. A negative type photosensitive resin forms an inversely tapered shape after the exposure and development. In the latter positive type case, it is possible to form a bank pattern by coating a positive type photosensitive resin material including a binder resin and a melamine resin on the substrate 1, and then exposing the same via a mask and patterning it. A positive type photosensitive resin also forms an inversely tapered shape after the exposure and development as is the case with a negative type one. In both cases of a positive type and negative type, in order to improve chemical resistance of the bank, a photoacid generator may be added to the photosensitive resin material. The invention is characterized in that a binder resin and a melamine resin are included in forming the bank through either of a printing method and a photolithographic system (positive type and negative type). In order to give light-shielding properties to a part or the whole of the bank, a black shielding member may be incorporated into the material to be used for a portion having light-shielding properties (hereinafter, referred to as a light-shielding layer). In order to prevent color mixture and color unevenness of a colored ink, it is preferred to incorporate an ink-repellent agent into a part or the whole of the bank.

The bank is pattern-formed by means of the printing method or the lithographic method. After that, burning is carried out under a temperature condition of 100 to 125° C., and the bank having a quadrangular or an inversely tapered shape can be obtained. When the bank is thermally cured at temperatures higher than 125° C., then the shape of the bank becomes bowl-like, and the bank having a quadrangular or an inversely tapered shape can not be obtained. On the other hand, when the bank is burned at temperatures lower than 100° C., then the resin of the bank dissolves in a colored ink discharged from an ink-jet apparatus. The burning time is preferably from 5 minutes to 60 minutes.

The bank is preferably formed to have a height of 1.5 μm or higher. It is formed to have a height of more preferably from 1.5 μm to 5 μm, further preferably from 2 μm to 5 μm. The height of the bank lower than 1.5 μm results in the occurrence of color mixture of colored inks. On the other hand, a too large height of the bank results in significant heat sagging, and the shape of the bank becomes bowl-like, not to allow the bank having a quadrangular or an inversely tapered shape to be obtained.

The bank may have one layer, or a multilayer structure including two or more layers. In a case of the bank having one layer, the number of the manufacturing process is small, thereby it is desirable since the productivity is good. When forming the bank having a large layer thickness, banks having the same pattern can be laminated to give a multilayer structure. In case where the bank of one layer is to be formed, it can be formed by using a printing method or a photolithographic system. On this occasion, light-shielding properties may be given to the whole bank to form a one-layer shielding layer. When forming the bank to have a multilayer structure, at least one layer thereof is preferably given with light-shielding properties to constitute a light-shielding layer. Hereinafter, such an example is described that, in a method for producing a multilayer bank, the lowermost layer is formed as a light-shielding layer and the upper layers are formed as non-shielding layers. But the invention is not limited to this constitution.

Firstly, a light-shielding layer is formed on the transparent substrate 1. The light-shielding layer can be formed by a printing method by using the above-described printing material, or a photolithographic system by using a photosensitive resin material, and, in addition, it may be also formed by a publicly known method other than these. For example, there can be mentioned such a method that a thin film of a metal or a metal oxide is formed on a substrate or non-shielding layer by means of such a method as sputtering and then the film is patterned by such technique as etching.

On the light-shielding layer having been formed on a transparent substrate, by means of a photolithographic system or a printing method, a non-shielding layer having been subjected to patterning processing in accordance with the pattern of the light-shielding layer is laminated in number of times corresponding to the necessity. By further forming banks having a certain height on the light-shielding layer, it is possible to sufficiently accept colored inks discharged by an ink-jet method in openings surrounded by banks, and, simultaneously, to obtain the effect of preventing color mixture due to inks. In case where the photolithographic system is used, even when a defect had occurred at forming the light-shielding layer, the pattern-processed photosensitive resin repairs the defect and functions as a bank portion sectioning pixels. Consequently, the color mixing due to inks caused by the defect in the light-shielding layer can be prevented. Further, in case where a non-shielding layer is formed by means of a photolithographic system using a positive type photosensitive resin material, the light-shielding layer previously formed to the substrate works as a mask to make back-side exposure possible. Therefore, the preparation of a particular mask is not necessary, so it is possible to achieve the lamination of the non-shielding layer at low cost with ease.

After forming the non-shielding layer having the same pattern with each other on the light-shielding layer, the laminate of a multilayer structure is burned under a condition of from 100° C. to 125° C. to harden, thereby forming the bank. After this, each of three colored inks is printed by means of a publicly known ink-jet system to form a substrate with a color pattern.

In the above-described example, the bank is formed to have a multilayer structure, wherein a non-shielding layer is laminated on a light-shielding layer on a transparent substrate. But the invention is not limited to this, and even when a bank has other embodiment, the effect of the invention can be obtained by using above-described predetermined materials and carrying out the burning under above-described conditions.

Hereinafter, components and materials included in the printing materials and photosensitive resin material for use in forming the bank are detailed.

The binder resin in the invention is one that sufficiently crosslinks with a melamine derivative through heating at low temperatures and gives solvent resistance to the bank. For the binder resin, one that crosslinks with a melamine derivative suffices, and such resins as containing an amino group, an amide group, a carboxyl group or a hydroxyl group are preferred because they effectively crosslink with a methylol group or a methoxymethyl group of melamine resin at low temperatures. Specific examples thereof include cresol-novolac resin, polyvinylphenol resin, acrylic resin and methacrylic resin. These binder resins may be used independently, or in a mixture of two or more types.

The melamine derivative in the invention is one that sufficiently crosslinks with the binder resin through heating at low temperatures to give solvent resistance to the bank. For the melamine derivative, compounds that have a methylol group or a methoxymethyl group suffice, and in particular, one having a large solubility for a solvent is preferred. Examples of melamine derivatives include such melamine compound as di-, tri-, tetra-, penta-, and hexa-methylol melamine, and those that can be obtained by reacting each of these compounds with formaldehyde etc. These melamine derivatives may be used independently, or in a mixture of two or more types.

The amount of the melamine derivative may be within a range from 1 to 50 parts by weight relative to 100 parts by weight of the binder resin, and is preferably 5 to 30 parts by weight. An amount less than 5 parts by weight resulted in the occurrence of such problem that the resin of the bank portions dissolved in a colored ink from an ink-jet apparatus, and an amount more than 30 parts by weight resulted in the occurrence of such problem that development could not be carried out when a photolithographic system was used.

The photoacid generator in the invention works to accelerate the dehydration reaction and the crosslinking reaction between the melamine derivative and the binder resin by the action of an acid that is generated upon the exposure. Among photoacid generators, those having a large solubility for a solvent are especially preferred. Specific examples thereof include such diaryliodonium as diphenyliodonium, ditolyliodonium, phenyl(4-anisyl)iodonium, bis(3-nitrophenyl)iodonium, bis(4-tert-butylphenyl)iodonium, bis(4-chlorophenyl)iodonium, bis(4-n-dodecylphenyl)iodonium, 4-isobutylphenyl(4-tolyl)iodonium, 4-isopropylphenyl(4-tolyl)iodonium, chloride, bromide, fluoroborate, hexafluorophosphate, hexafluoroarsenate and aromatic sulfonic acid salt of such triarylsulfonium as triphenylsulfonium, tetrakis(pentafluorophenyl)borate, such sulfonium organoboron complex salt as diphenylphenacylsulfonium(n-butyl)triphenylborate, such triazine compounds as 2-methyl-4,6-bistrichloromethyl triazine, 2-(4-methoxyphenyl)-4,6-bistrichloromethyl triazine and 2-{2-(5-methylfuran-2-yl)ethenyl}-4,6-bis(trichloromethyl)-s-triazine, and such diazonaphthoquinone compounds as 1,2-naphthoquinonediazide, sodium 1,2-naphthoquinonediazide-4-sulfonate, sodium 1,2-naphthoquinonediazide-5-sulfonate, 1,2-naphthoquinonediazide-4-sulfonic acid ester derivatives and 1,2-naphthoquinonediazide-5-sulfonic acid ester derivatives.

The addition amount of the photoacid generator may be within a range from 1 to 50 parts by weight relative to 100 parts by weight of the binder resin, and is preferably from 3 to 30 parts by weight.

For the compound having radical polymerization properties, for example, monomer and oligomer having a vinyl group or an allyl group, or polymer having a vinyl group or an allyl group at the end or on a side branch can be employed. Specific examples include (meth)acrylic acid and salts thereof, (meth)acrylic acid esters, (meth)acrylamides, maleic anhydride, maleic acid esters, itaconic acid esters, styrenes, vinyl ethers, vinyl esters, N-vinyl heterocycles, allyl ethers, allyl esters and derivatives thereof. Examples of preferred compounds can include, but not limited to, such multifunctional acrylate having a relatively low molecular weight as pentaerythritol triacrylate, trimethylolpropane triacrylate, pentaerythritol tetraacrylate, ditrimethylolpropane tetraacrylate and dipentaerythritol penta- and hexa-acrylate. These compounds having radical polymerization properties may be used independently, or in a mixture of two or more types. The amount of the compound having radical polymerization properties may be within a range from 1 to 200 parts by weight relative to 100 parts by weight of binder resin, and is preferably from 50 to 150 parts by weight.

Photopolymerization initiators are a compound that generates radicals through exposure to crosslink the binder resin via a compound having radical polymerization properties. Specific examples of the photopolymerization initiator can include such benzophenone compounds as benzophenone, 4,4′-bis(dimethylamino)benzophenone and 4,4′-bis(diethylamino)benzophenone, such acetophenone derivatives as 1-hydroxycyclohexylacetophenone, 2,2-dimethoxy-2-phenylacetophenone and 2-methyl-1-[4-(methylthio)phenyl]-2-morpholinopropane-1-one, thioxanthone, such thioxanthone derivatives as 2,4-diethylthioxanthone, 2-isopropylthioxanthone and 2-chlorothioxanthone, such anthraquinone derivatives as 2-methylanthraquinone, 2-ethylanthraquinone, 2-t-butylanthraquinone and chloroanthraquinone, such benzoin ether derivatives as benzoin methyl ether, benzoin ethyl ether and benzoin phenyl ether, such acylphosphine derivative as phenylbis-(2,4,6-trimethylbenzoyl)-phosphine oxide, such lophine dimmer as 2-(o-chlorophenyl)-4,5-bis(4′-methylphenyl)imidazolyl dimer, such N-arylglycine as N-phenylglycine, such organic azides as 4,4′-diazidochalkone, 3,3′,4,4′-tetra(tert-butylperoxycarboxy)benzophenone and quinonediazide group-containing compounds. These photopolymerization initiators may be used independently, or in a mixture of two or more types. The amount of the photopolymerization initiator may be within a range from 0.1 to 50 parts by weight relative to 100 parts by weight of the binder resin, and is preferably from 1 to 20 parts by weight.

The printing material or the photosensitive resin material for use in forming the bank may be diluted with an appropriate solvent according to need. The solvent is dried after the printing or coating onto the base material. Specific examples of usable solvents include dichloromethane, dichloroethane, chloroform, acetone, cyclohexanone, ethyl acetate, 2-methoxyethanol, 2-ethoxyethanol, 2-butoxyethanol, 2-ethylethoxy acetate, 2-butoxyethyl acetate, 2-methoxyethyl ether, 2-ethoxyethyl ether, 2-(2-ethoxyethoxy)ethanol, 2-(2-butoxyethoxy)ethanol, 2-(2-ethoxyethoxy)ethyl acetate, 2-(2-butoxyethoxy)ethyl acetate, propylene glycol monomethyl ether, propylene glycol monomethyl ether acetate, diethylene glycol dimethyl ether and tetrahydrofuran. The solvent is desirably used in such an amount that results in a homogenous coating film with no pinhole and coating unevenness when the material is printed or coated on the substrate, and the printing material or the photosensitive resin material is preferably prepared so that the content ratio of the solvent is from 50 to 97% by weight relative to the total weight of the material.

The black light-shielding member is a member that works to give light-shielding properties to the bank and to improve the contrast of a substrate with a color pattern. For the black light-shielding member, black pigment, black dye, carbon black, aniline black, graphite, iron black, titanium oxide, inorganic pigment and organic pigment can be employed. These black light-shielding members may be used independently, or in a mixture of two or more types.

The ink-repellent agent is a material that gives ink-repellent properties for the colored ink to the bank. The ink-repellent agent may be used by previously adding it to the printing material or the photosensitive resin material for use in forming the bank. For the ink-repellent agent, a fluorine-containing compound or a silicon-containing compound can be used, and the use of these in a mixture is more preferred. Specific examples of the fluorine-containing compound include such fluorine-containing resins as vinylidene fluoride, vinyl fluoride and ethylene trifluoride, and copolymers thereof. These fluorine-containing compounds may be used independently, or in a mixture of two or more types. For the silicon-containing compound, silicone resin and silicone rubber having organic silicon in the main chain or side branch and containing siloxane component can be mentioned. These silicon-containing compounds may be used independently, or in a mixture of two or more types. The fluorine-containing compound and the silicon-containing compound, or other ink-repellent component may be used in combination. The amount of the fluorine-containing compound or a silicon-containing compound included in the printing material or the photosensitive resin material in the invention is preferably from 0.01% by weight to 10% by weight relative to the total parts by weight.

In addition, to the printing material or the photosensitive resin material for use in forming the bank, such an additive having compatibility as a leveling agent, a chain transfer agent, a stabilizer, a sensitizing dye, a surfactant or a coupling agent can be added.

According to the invention, the bank portions that do not dissolve in such an organic solvent as that in a colored ink, and have a quadrangular or inversely tapered shape could be obtained. Consequently, a substrate with a color pattern with high resolution that is provided with flat colored layers free of color unevenness could be obtained.

In addition, according to the invention, the bank portions that have a thickness of 1.5 μm or more, do not dissolve in such an organic solvent as that in a colored ink, and have a quadrangular or inversely tapered shape could be obtained. Consequently, a substrate with a color pattern with high resolution that is provided with flat colored layers free of color unevenness and color mixture could be obtained.

### EXAMPLES

Hereinafter, the present invention is detailed with reference to Examples and Comparative Examples, but the invention is not limited to the embodiment.

### Comparative Examples 1 to 8

### (Formation of Bank)

For a transparent substrate, an alkali free glass (“#1737,” Corning) was used. A photosensitive resin composition having the following composition ratio was sufficiently kneaded with a three-roller system, and then coated on the transparent substrate in a thickness of 2.0 μm.

### [Photosensitive Resin Composition A]

| | |
|---|---|
| Cresol-novolac resin “EP4050G” (Asahi Organic | 20 parts by weight |
| Chemicals Industry) | |
| Cyclohexanone | 80 parts by weight |
| Carbon pigment “MA-8” (Mitsubishi Materials) | 23 parts by weight |
| Dispersing agent “Solsperse #5000” (ZENECA) | 1.4 parts by weight |
| Radically polymerizable compound | 5 parts by weight |
| “trimethylolpropane triacrylate” (Osaka | |
| Organic Chemical Industry) | |
| Photopolymerization initiator “Irgacure 369” (Ciba | 2 parts by weight |
| Specialty Chemicals) | |
| Fluorine-containing compound “F179” | 0.5 part by weight |
| (DAINIPPON INK AND CHEMICALS) | |

Then, the transparent substrate was pre-baked, followed by an exposure of 100 mJ/cm² with an ultra-high pressure mercury lamp via a photo mask having a lattice-shaped pattern, which was then subjected to development treatment. Subsequently, the transparent substrate was heated in an oven under temperature conditions as listed in Table 1, 1 to 8 for 30 minutes (Comparative Examples 1 to 8 as shown in Table 1).

For the purpose of checking the shape of the formed bank, the cross-section thereof was observed with a scanning electron microscope. Banks formed in Comparative Examples 1 to 4 had an inversely tapered shape. In banks formed in Comparative Examples 5 to 8, heat sagging occurred to give a rounded bowl-like shape. These results are shown in Table 1.

Then, the OD value (optical density) of the banks was measured to give 6. Thus, it was confirmed that the banks have sufficient light-shielding properties and each of these can be employed for the light-shielding layer.

The OD value is defined as follows. While indicating the strength of the incident light by I₀ and the strength of the transmitted light by I when visible light is transmitted through a 1 μm sample, the OD value is obtained from the following formula.

OD value=−log(I/I₀)

Next, on the substrate having the bank, colored inks were printed with an ink-jet apparatus. Each of banks formed in Comparative Examples 1-7 dissolved in the colored ink. The bank formed in Comparative Example 8 also slightly dissolved in the colored ink to result in the reduction in the film thickness. These results are shown in Table 1.

### Examples 1-3 and Reference Examples 1 to 5

### (Formation of Bank)

For a transparent substrate, an alkali free glass (“#1737,” Corning) was used. A photosensitive resin composition having the following composition ratio was sufficiently kneaded with a three-roller system, and then coated on the transparent substrate in a thickness of 2.0 μm.

### [Photosensitive Resin Composition B]

| | |
|---|---|
| Cresol-novolac resin “EP4050G” (Asahi | 20 parts by weight |
| Organic Chemicals Industry) | |
| Melamine resin “MX-706” (Sanwa Chemical) | 4 parts by weight |
| Radically polymerizable compound | 5 parts by weight |
| “trimethylolpropane triacrylate” (Osaka | |
| Organic Chemical Industry) | |
| Photopolymerization initiator “Irgacure 369” (Ciba | 2 parts by weight |
| Specialty Chemicals) | |
| Cyclohexanone | 80 parts by weight |
| Carbon pigment “MA-8” (Mitsubishi Materials) | 23 parts by weight |
| Dispersing agent “Solsperse #5000” (ZENECA) | 1.4 parts by weight |
| Fluorine-containing compound “F179” | 0.5 part by weight |
| (DAINIPPON INK AND CHEMICALS) | |

Then, the transparent substrate was pre-baked, followed by an exposure of 100 mJ/cm² with an ultra-high pressure mercury lamp via a photo mask having a lattice-shaped pattern and, further, which was then subjected to development treatment. Subsequently, the transparent substrate was heated in an oven under temperature conditions as listed in Table 1, 1 to 8 for 30 minutes (Examples 1 to 3 and Reference Examples 1 to 5 as shown in Table 1).

For the purpose of checking the shape of the formed bank, the cross-section thereof was observed with a scanning electron microscope. Banks formed in Comparative Example 9 and Examples 1 to 3 had an inversely tapered shape. In banks formed in Comparative Examples 10 to 13, heat sagging occurred to give a rounded bowl-like shape. These results are shown in Table 1.

Then, the OD value (optical density) of the banks was measured to give 6. Thus, it was confirmed that the banks have sufficient light-shielding properties and each of these can be employed for the light-shielding layer.

Next, on the substrate having the bank, colored inks were printed with an ink-jet apparatus. The bank formed in Comparative Example 9 dissolved in the colored ink. The banks formed in Examples 1 to 3 and Comparative Examples 10 to 13 did not dissolve in the colored ink. The contact angle between the side surface of the banks formed in Examples 1 to 3 and the colored ink was measured to give around 30 degrees for respective banks. Thus, it was confirmed that they have further ink-repellent properties for the colored ink. These results are shown in Table 1.

### Examples 5 to 7 and Reference Examples 6 to 10

### (Formation of Bank)

For a transparent substrate, an alkali free glass (“#1737,” Corning) was used. A photosensitive resin composition having the following composition ratio was sufficiently kneaded with a three-roller system, and then coated on the transparent substrate in a thickness of 2.0 μm.

### [Photosensitive Resin Composition C]

| | |
|---|---|
| Cresol-novolac resin “EP4050G” (Asahi | 20 parts by weight |
| Organic Chemicals Industry) | |
| Melamine resin “MX-706” (Sanwa Chemical) | 6 parts by weight |
| Radically polymerizable compound | 5 parts by weight |
| “trimethylolpropane triacrylate” (Osaka | |
| Organic Chemical Industry) | |
| Photopolymerization initiator “Irgacure 369” (Ciba | 2 parts by weight |
| Specialty Chemicals) | |
| Cyclohexanone | 80 parts by weight |
| Carbon pigment “MA-8” (Mitsubishi Materials) | 23 parts by weight |
| Dispersing agent “Solsperse #5000” (ZENECA) | 1.4 parts by weight |
| Fluorine-containing compound “F179” | 0.5 part by weight |
| (DAINIPPON INK AND CHEMICALS) | |

Then, the transparent substrate was pre-baked, followed by an exposure of 100 mJ/cm² with an ultra-high pressure mercury lamp via a photo mask having a lattice-shaped pattern, which was then subjected to development treatment. Subsequently, the transparent substrate was heated in an oven under temperature conditions as shown in Table 1, 1 to 8 for 30 minutes (Examples 5 to 7 and Reference Examples 6 to 10 as shown in Table 1).

For the purpose of checking the shape of the formed bank, the cross-section thereof was observed with a scanning electron microscope. Banks formed in Examples 5 to 7 and Reference Example 6 had an inversely tapered shape. In banks formed in Reference Examples 7 to 10, heat sagging occurred to give a rounded bowl-like shape. These results are shown in Table 1.

Then, the OD value (optical density) of the banks was measured to give 6. Thus, it was confirmed that the banks have sufficient light-shielding properties and each of these can be employed for the light-shielding layer.

Next, on the substrate having the bank, colored inks were printed with an ink-jet apparatus. The bank formed in Reference Example 6 partly dissolved in the colored ink. The banks formed in Examples 5 to 7 and Reference Examples 7 to 10 did not dissolve in the colored ink. The contact angle between the side surface of the banks formed in Examples 5 to 7 and the colored ink was measured to give around 30 degrees for respective banks. Thus, it was confirmed that they have further ink-repellent properties for the colored ink. These results are shown in Table 1.

### Examples 8 to 11 and Reference Examples 11 to 14

### (Formation of Bank)

For a transparent substrate, an alkali free glass (“#1737,” Corning) was used. A photosensitive resin composition having the following composition ratio was sufficiently kneaded with a three-roller system, and then coated on the transparent substrate in a thickness of 2.0 μm.

### [Photosensitive Resin Composition D]

| | | |
|---|---|---|
| Cresol-novolac resin “EP4050G” (Asahi Organic | 20 | parts by weight |
| Chemicals Industry) | | |
| Melamine resin “MX-706” (Sanwa Chemical) | 6 | parts by weight |
| Pentaerythritol triacrylate “V#300” (Osaka Organic | 5 | parts by weight |
| Chemical Industry) | | |
| Photopolymerization initiator “Irgacure 369” (Ciba | 1 | part by weight |
| Specialty Chemicals) | | |
| Photoacid generator (2-{2-(5-methylfuran-2-yl) | 3 | part by weight |
| ethenyl}-4,6-bis (trichloromethyl)-s-triazine) | | |
| Cyclohexanone | 80 | parts by weight |
| Carbon pigment “MA-8” (Mitsubishi Materials) | 23 | parts by weight |
| Dispersing agent “Solsperse #5000” (ZENECA) | 1.4 | parts by weight |
| Fluorine-containing compound “F179” | 0.5 | part by weight |
| (DAINIPPON INK AND CHEMICALS) | | |

Then, the transparent substrate was pre-baked, followed by an exposure of 100 mJ/cm² with an ultra-high pressure mercury lamp via a photo mask having a lattice-shaped pattern, which was then subjected to development treatment. Subsequently, the transparent substrate was heated in an oven under temperature conditions as shown in Table 2, 1 to 8 for 30 minutes (Examples 8 to 11 and Reference Examples 11 to 14 as shown in Table 2).

For the purpose of checking the shape of the formed bank, the cross-section thereof was observed with a scanning electron microscope. Banks formed in Examples 8 to 11 had an inversely tapered shape. In banks formed in Reference Examples 11 to 14, heat sagging occurred to give a rounded bowl-like shape. These results are shown in Table 2.

Then, the OD value (optical density) of the banks was measured to give 6. Thus, it was confirmed that the banks have sufficient light-shielding properties and each of these can be employed for the light-shielding layer.

Next, on the substrate having the bank, colored inks were printed with an ink-jet apparatus. The banks formed in Examples 8 to 11 and Reference Examples 11 to 14 did not dissolve in the colored ink. The contact angle between the side surface of the banks formed in Examples 8 to 11 and the colored ink was measured to give around 30 degrees for respective banks. Thus, it was confirmed that they have further ink-repellent properties for the colored ink. These results are shown in Table 2.

### Comparative Examples 9 to 16

### (Formation of Bank)

For a transparent substrate, an alkali free glass (“#1737,” Corning) was used. A photosensitive resin composition having the following composition ratio was sufficiently kneaded with a three-roller system, and then coated on the transparent substrate in a thickness of 2.0 μm.

### [Photosensitive Resin Composition E] (Positive Type)

| | | |
|---|---|---|
| Binder resin “SPR6812” (Rohm and Haas | 100 | parts by weight |
| Electronic Materials) | | |
| Carbon pigment “MA-8” (Mitsubishi Materials) | 23 | parts by weight |
| Dispersing agent “Solsperse #5000” (ZENECA) | 1.4 | parts by weight |
| Fluorine-containing compound “F179” | 0.5 | part by weight |
| (DAINIPPON INK AND CHEMICALS) | | |

Then, the transparent substrate was pre-baked, followed by an exposure of 100 mJ/cm² with an ultra-high pressure mercury lamp via a photo mask having a lattice-shaped pattern, which was then subjected to development treatment. Subsequently, the transparent substrate was heated in an oven under temperature conditions as shown in Table 2, 1 to 8 for 30 minutes (Comparative Examples 9 to 16 as shown in Table 2).

For the purpose of checking the shape of the formed bank, the cross-section thereof was observed with a scanning electron microscope. Banks formed in Comparative Examples 9 to 12 had an inversely tapered shape. In banks formed in Comparative Examples 13 to 16, heat sagging occurred to give a rounded bowl-like shape. These results are shown in Table 2.

Then, the OD value (optical density) of the banks was measured to give 6. Thus, it was confirmed that the banks have sufficient light-shielding properties and each of these can be employed for the light-shielding layer.

Next, on the substrate having the bank, colored inks were printed with an ink-jet apparatus. Each of the banks formed in Comparative Examples 9 to 16 dissolved in the colored ink. These results are shown in Table 2.

### Examples 12 to 14 and Reference Examples 15 to 19

### (Formation of Bank)

For a transparent substrate, an alkali free glass (“#1737,” Corning) was used. A photosensitive resin composition having the following composition ratio was sufficiently kneaded with a three-roller system, and then coated on the transparent substrate in a thickness of 2.0 μm.

### [Photosensitive Resin Composition F] (Positive Type)

| | | |
|---|---|---|
| Binder resin “SPR6812” (Rohm and Haas | 100 | parts by weight |
| Electronic Materials) | | |
| Melamine resin “MX-706” (Sanwa Chemical) | 20 | parts by weight |
| Carbon pigment “MA-8” (Mitsubishi Materials) | 23 | parts by weight |
| Dispersing agent “Solsperse #5000” (ZENECA) | 1.4 | parts by weight |
| Fluorine-containing compound “F179” | 0.5 | part by weight |
| (DAINIPPON INK AND CHEMICALS) | | |

Then, the transparent substrate was pre-baked, followed by an exposure of 100 mJ/cm² with an ultra-high pressure mercury lamp via a photo mask having a lattice-shaped pattern, which was then subjected to development treatment. Subsequently, the transparent substrate was heated in an oven under temperature conditions as shown in Table 2, 1 to 8 for 30 minutes (Examples 12 to 14 and Reference Examples 15 to 19 as shown in Table 2).

For the purpose of checking the shape of the formed bank, the cross-section thereof was observed with a scanning electron microscope. Banks formed in Examples 12 to 14 had an inversely tapered shape. In banks formed in Reference Examples 15 to 19, heat sagging occurred to give a rounded bowl-like shape. These results are shown in Table 2.

Then, the OD value (optical density) of the banks was measured to give 6. Thus, it was confirmed that the banks have sufficient light-shielding properties and each of these can be employed for the light-shielding layer.

Next, on the substrate having the bank, colored inks were printed with an ink-jet apparatus. The banks formed in Examples 12 to 14 and Reference Examples 15 to 19 did not dissolve in the colored ink. Further, the contact angle between the side surface of the banks formed in Examples 12 to 14 and the colored ink was measured to give around 30 degrees for respective bank. Thus, it was confirmed that they have further ink-repellent properties for the colored ink. These results are shown in Table 2.

### Example 15

### (Formation of Bank)

On the bank (thickness: 2 μm) on the transparent substrate formed in Comparative Example 2, the photosensitive resin composition having the following composition ratio was coated in a thickness of 2.0 μm.

### [Photosensitive Resin Composition X]

| | | |
|---|---|---|
| Positive type binder resin “SPR6812” | 100 | parts by weight |
| (Rohm and Haas Electronic Materials) | | |
| Melamine resin “MX-706” (Sanwa Chemical) | 20 | parts by weight |
| Fluorine-containing compound “F179” | 0.5 | part by weight |
| (DAINIPPON INK AND CHEMICALS) | | |

Then, the transparent substrate was pre-baked, followed by a back-side exposure of 100 mJ/cm² with an ultra-high pressure mercury lamp while utilizing the bank on the transparent substrate formed in Comparative Example 2 for a mask, which was then subjected to development treatment. Subsequently, the transparent substrate was heated in an oven at 100° C. for 30 minutes.

For the purpose of checking the shape of the formed bank having a laminated structure, the cross-section thereof was observed with a scanning electron microscope. The bank having a laminated structure formed in Example 15 had an inversely tapered shape.

Then, the OD value (optical density) of the bank was measured to give 6. Thus, it was confirmed that the bank has sufficient light-shielding properties and it can be employed for the light-shielding layer.

Next, on the substrate having the bank, colored inks were printed with an ink-jet apparatus. The bank did not dissolve in the colored ink. Further, the contact angle between the side surface of the bank and the colored ink was measured to give around 30 degrees. Thus, it was confirmed that it has further ink-repellent properties for the colored ink. These results are shown in Table 3.

### Comparative Example 17

### (Formation of Bank)

On the bank (thickness: 2 μm) on the transparent substrate formed in Comparative Example 2, the photosensitive resin composition having the following composition ratio was coated in a thickness of 2.0 μm.

### [Photosensitive Resin Composition X]

| | | |
|---|---|---|
| Positive type binder resin “SPR6812” | 100 | parts by weight |
| (Rohm and Haas Electronic Materials) | | |
| Fluorine-containing compound “F179” | 0.5 | part by weight |
| (DAINIPPON INK AND CHEMICALS) | | |

Then, the transparent substrate was pre-baked, followed by a back-side exposure of 100 mJ/cm² with an ultra-high pressure mercury lamp while utilizing the bank on the transparent substrate formed in Comparative Example 2 for a mask, which was then subjected to development treatment. Subsequently, the transparent substrate was heated in an oven at 100° C. for 30 minutes.

For the purpose of checking the shape of the formed bank having a laminated structure, the cross-section thereof was observed with a scanning electron microscope. The bank having a laminated structure formed in Comparative Example 35 had an inversely tapered shape.

Then, the OD value (optical density) of the bank was measured to give 6. Thus, it was confirmed that the bank has sufficient light-shielding properties and it can be employed for the light-shielding layer.

Next, on the substrate having the bank, colored inks were printed with an ink-jet apparatus. The bank dissolved in the colored ink. These results are shown in Table 3.

### Example 16

### (Formation of Bank)

On the bank (thickness: 2 μm) on the transparent substrate formed in Example 1, the photosensitive resin composition having the following composition ratio was coated in a thickness of 2.0 μm.

### [Photosensitive Resin Composition X]

| | | |
|---|---|---|
| Positive type binder resin “SPR6812” (Rohm and | 100 | parts by weight |
| Haas Electronic Materials) | | |
| Melamine resin “MX-706” (Sanwa Chemical) | 20 | parts by weight |
| Fluorine-containing compound “F179” | 0.5 | part by weight |
| (DAINIPPON INK AND CHEMICALS) | | |

Then, the transparent substrate was pre-baked, followed by a back-side exposure of 100 mJ/cm² with an ultra-high pressure mercury lamp while utilizing the bank on the transparent substrate formed in Example 1 for a mask, which was then subjected to development treatment. Subsequently, the transparent substrate was heated in an oven at 100° C. for 30 minutes.

For the purpose of checking the shape of the formed bank having a laminated structure, the cross-section thereof was observed with a scanning electron microscope. The bank having a laminated structure formed in Example 16 had an inversely tapered shape.

Then, the OD value (optical density) of the bank was measured to give 6. Thus, it was confirmed that the bank has sufficient light-shielding properties and it can be employed for the light-shielding layer.

Next, on the substrate having the bank, colored inks were printed with an ink-jet apparatus. The bank did not dissolve in the colored ink. Further, the contact angle between the side surface of the bank and the colored ink was measured to give around 30 degrees. Thus, it was confirmed that it has further ink-repellent properties for the colored ink. These results are shown in Table 3.

TABLE 1

| | | | photosensitive resin | | | photosensitive resin | | | photosensitive resin | |
|---|---|---|---|---|---|---|---|---|---|---|
| | | | composition A | | | composition B | | | composition C | |
| | temperature | | | chemical | | | chemical | | | chemical |
| condition | (° C.) | | configuration | resistance | | configuration | resistance | | configuration | resistance |
| 1 | 75 | Comparative | [symbol] | x | Reference | [symbol] | x | Reference | [symbol] | Δ |
| | | Example 1 | | | Example 1 | | | Example 6 | | |
| 2 | 100 | Comparative | [symbol] | x | Example 1 | [symbol] | ∘ | Example 5 | [symbol] | ∘ |
| | | Example 2 | | | | | | | | |
| 3 | 112 | Comparative | [symbol] | x | Example 2 | [symbol] | ∘ | Example 6 | [symbol] | ∘ |
| | | Example 3 | | | | | | | | |
| 4 | 125 | Comparative | [symbol] | x | Example 3 | [symbol] | ∘ | Example 7 | [symbol] | ∘ |
| | | Example 4 | | | | | | | | |
| 5 | 137 | Comparative | [symbol] | x | Reference | [symbol] | ∘ | Reference | [symbol] | ∘ |
| | | Example 5 | | | Example 2 | | | Example 7 | | |
| 6 | 150 | Comparative | [symbol] | x | Reference | [symbol] | ∘ | Reference | [symbol] | ∘ |
| | | Example 6 | | | Example 3 | | | Example 8 | | |
| 7 | 167 | Comparative | [symbol] | x | Reference | [symbol] | ∘ | Reference | [symbol] | ∘ |
| | | Example 7 | | | Example 4 | | | Example 9 | | |
| 8 | 180 | Comparative | [symbol] | Δ | Reference | [symbol] | ∘ | Reference | [symbol] | ∘ |
| | | Example 8 | | | Example 5 | | | Example 10 | | |

TABLE 2

| | | | photosensitive resin | | | photosensitive resin | | | photosensitive resin | |
|---|---|---|---|---|---|---|---|---|---|---|
| | | | composition D | | | composition E | | | composition F | |
| | temperature | | | chemical | | | chemical | | con- | chemical |
| condition | (° C.) | | configuration | resistance | | configuration | resistance | | figuration | resistance |
| 1 | 75 | Example 8 | [symbol] | ∘ | Comparative | [symbol] | x | Reference | [symbol] | x |
| | | | | | Example 9 | | | Example 15 | | |
| 2 | 100 | Example 9 | [symbol] | ∘ | Comparative | [symbol] | x | Example 12 | [symbol] | ∘ |
| | | | | | Example 10 | | | | | |
| 3 | 112 | Example 10 | [symbol] | ∘ | Comparative | [symbol] | x | Example 13 | [symbol] | ∘ |
| | | | | | Example 11 | | | | | |
| 4 | 125 | Example 11 | [symbol] | ∘ | Comparative | [symbol] | x | Example 14 | [symbol] | ∘ |
| | | | | | Example 12 | | | | | |
| 5 | 137 | Reference | [symbol] | ∘ | Comparative | [symbol] | x | Reference | [symbol] | ∘ |
| | | Example 11 | | | Example 13 | | | Example 16 | | |
| 6 | 150 | Reference | [symbol] | ∘ | Comparative | [symbol] | x | Reference | [symbol] | ∘ |
| | | Example 12 | | | Example 14 | | | Example 17 | | |
| 7 | 167 | Reference | [symbol] | ∘ | Comparative | [symbol] | x | Reference | [symbol] | ∘ |
| | | Example 13 | | | Example 15 | | | Example 18 | | |
| 8 | 180 | Reference | [symbol] | ∘ | Comparative | [symbol] | Δ | Reference | [symbol] | ∘ |
| | | Example 14 | | | Example 16 | | | Example 19 | | |

TABLE 3

| | | | chemical |
|---|---|---|---|
| | | configuration | resistance |
| Example 16 | A derivative of an meramine | [symbol] | ◯ |
| | resin is added to both light | | |
| | shielding portion 4 and non- | | |
| | shielding portion 5. | | |
| Example 15 | A derivative of a meramine | [symbol] | ◯ |
| | resin is added to non- | | |
| | shielding portion 5 | | |
| Comparative | A derivative of a meramine | [symbol] | X |
| Example 17 | resin is not added to both light | | |
| | shielding portion and non- | | |
| | shielding portion5. | | |

### Example 17

A bank was formed in the totally same way as in Example 5 except for using 2-{2-(5-methylfuran-2-yl)ethenyl}-4,6-bis(trichloromethyl-s-triazine “TME-triazine” (Sanwa Chemical) for a photoacid generator.

### Example 18

On the bank formed in Example 17, a bank was laminated in the same way as illustrated in Example 16 to form a bank having a multilayer structure.

### Example 19

A bank was formed in the same way as in Example 1 except for using poly(4-vinylphenol) “Marukalinker MS-1” (Maruzen Petrochemical) in place of the cresol-novolac resin.

### Example 20

On the bank formed in Example 19, a bank was laminated in the same way as illustrated in Example 16 to form a bank having a multilayer structure.

### Example 21

A bank was formed in the same way as in Example 1 except for using an acrylate resin “Cyclomer-P ACA200M” (Daicel Chemical Industries) in place of the cresol-novolac resin.

### Example 22

On the bank formed in Example 21, a bank was laminated in the same way as illustrated in Example 16 to form a bank having a multilayer structure.

### Example 23

A bank was formed in the same way as in Example 1 except for using a bisphenol-A type liquid epoxy resin “R-140p” (Mitsui Chemicals) in place of the cresol-novolac resin.

### Example 24

On the bank formed in Example 23, a bank was laminated in the same way as illustrated in Example 16 to form a bank having a multilayer structure.

### Example 25

A bank was formed in the same way as in Example 1 except for using a methylated melamine resin “Sumimal M-100” (Sumitomo Chemical) for melamine resin.

### Example 26

On the bank formed in Example 25, a bank was laminated in the same way as illustrated in Example 16 to form a bank having a multilayer structure.

### Example 27

A bank was formed in the totally same way as in Example 9 except for using 1 part by weight of triphenyl sulfonium salt “UVI-6992” (Dow Chemical) for a photoacid generator.

### Example 28

On the bank formed in Example 27, a bank was laminated in the same way as illustrated in Example 16 to form a bank having a multilayer structure.

### Example 29

A bank was formed in the totally same way as in Example 9 except for using 3 parts by weight of 1,2-naphthoquinone-(2)-diazido-5-sulfonic acid ester “4NT-250” (Toyo Gosei) for a photoacid generator.

### Example 30

On the bank formed in Example 29, a bank was laminated in the same way as illustrated in Example 16 to form a bank having a multilayer structure.

For the purpose of checking the shape of the banks formed in Examples 17 to 30, the cross-section thereof was observed with a scanning electron microscope. Each of the banks had an inversely tapered shape. Then, the OD value (optical density) of the banks in Examples 17 to 30 was measured to give 6. Thus, it was confirmed that each of the banks has sufficient light-shielding properties and it can be employed for the light-shielding layer.

Next, on the substrate having the bank, colored inks were printed with an ink-jet apparatus. Respective banks did not dissolve in the colored ink. Further, the contact angle between the side surface of the banks and the colored ink was measured to give around 30 degrees. Thus, it was confirmed that they have further ink-repellent properties for the colored ink.

### Example 31 and Reference Example 20

### (Formation of Bank)

For a transparent substrate, an alkali free glass (“#1737,” Corning) was used. A photosensitive resin composition having the following composition ratio was sufficiently kneaded with a three-roller system, and then coated on the transparent substrate in a thickness of 1.0 μm.

### [Photosensitive Resin Composition B]

| | | |
|---|---|---|
| Cresol-novolac resin “EP4050G”(Asahi Organic | 20 | parts by weight |
| Chemicals Industry) | | |
| Melamine resin “MX-706” (Sanwa Chemical) | 6 | parts by weight |
| Cyclohexanone | 80 | parts by weight |
| Carbon pigment “MA-8” (Mitsubishi Materials) | 23 | parts by weight |
| Dispersing agent “Solsperse #5000” (ZENECA) | 1.4 | parts by weight |
| Pentaerythritol triacrylate “V#300” (Osaka Organic | 5 | parts by weight |
| Chemical Industry) | | |
| Photopolymerization initiator “Irgacure 369” | 1 | part by weight |
| (Ciba Specialty Chemicals) | | |
| Fluorine-containing compound “F179” | 0.5 | part by weight |
| (DAINIPPON INK AND CHEMICALS) | | |

Then, the transparent substrate was pre-baked, followed by an exposure of 100 mJ/cm² with an ultra-high pressure mercury lamp via a photo mask having a lattice-shaped pattern, which was then subjected to development treatment. Further, formed were a bank heated in an oven at a post-baking temperature of 100° C. for 30 minutes (Example 31), and a bank heated in an oven at a post-baking temperature of 150° C. for 30 minutes (Reference Example 20). Shapes of these banks are shown in Table 4.

For the purpose of checking the shape of the formed banks, the cross-section thereof was observed with a scanning electron microscope. The bank formed in Example 31 had an inversely tapered shape.

Then, the OD value (optical density) of the banks was measured to give 6. Thus, it was confirmed that the banks have sufficient light-shielding properties and each of these can be employed for the light-shielding layer.

Next, on the substrate having the bank, colored inks were printed with an ink-jet apparatus. The banks formed in Examples 31 and Reference Example 20 did not dissolve in the colored ink. The contact angle between the side surface of the bank formed in Example 31 and the colored ink was measured to give around 30 degrees. Thus, it was confirmed that the bank has further ink-repellent properties for the colored ink. These results are shown in Table 4.

### Examples 32 to 36, Reference Examples 21 to 25

On the bank (thickness: 1 μm) formed in Example 31, a photosensitive resin composition having the following composition ratio was coated in a thickness of 0.5 μm, 1.0 μm, 2.0 μm, 3.0 μm, or 4.0 μm.

### [Photosensitive Resin Composition B]

| | | |
|---|---|---|
| Cresol-novolac resin “EP4050G” (Asahi Organic | 20 | parts by weight |
| Chemicals Industry) | | |
| Melamine resin “MX-706” (Sanwa Chemical) | 6 | parts by weight |
| Cyclohexanone | 80 | parts by weight |
| Pentaerythritol triacrylate “V#300” (Osaka Organic | 5 | parts by weight |
| Chemical Industry) | | |
| Photopolymerization initiator “Irgacure 369” (Ciba | 1 | part by weight |
| Specialty Chemicals) | | |
| Fluorine-containing compound “F179” | 0.5 | part by weight |
| (DAINIPPON INK AND CHEMICALS) | | |

Then, the transparent substrate was pre-baked, followed by an exposure of 100 mJ/cm² with an ultra-high pressure mercury lamp via a photo mask having a lattice-shaped pattern, which was then subjected to development treatment. Further, formed were banks heated in an oven at a post-baking temperature of 100° C. for 30 minutes (Examples 32 to 36), and banks heated in an oven at a post-baking temperature of 150° C. for 30 minutes (Reference Examples 21 to 25). Shapes of these banks are shown in Table 4.

For the purpose of checking the shape of the formed banks, the cross-section thereof was observed with a scanning electron microscope. The banks formed in Examples 32 to 36 had an inversely tapered shape. In banks formed in reference Examples 21 to 25, heat sagging occurred to give a rounded bowl-like shape. These results are shown in Table 4.

Then, the OD value (optical density) of the banks was measured to give 3. Thus, it was confirmed that the banks have sufficient light-shielding properties and each of these can be employed for the light-shielding layer.

Next, on the substrate having the bank, colored inks were printed with an ink-jet apparatus. The banks formed in Examples 32 to 36 and Reference Examples 21 to 25 did not dissolve in the colored ink. The contact angle between the side surface of the banks formed in Examples 32 to 36 and the colored ink was measured to give around 30 degrees for respective banks. Thus, it was confirmed that they have further ink-repellent properties for the colored ink. These results are shown in Table 4.

### Comparative Example 18

A photosensitive resin composition having the following composition ratio was sufficiently kneaded with a three-roller system, and then coated on the transparent substrate in a thickness of 1.0 μm.

### [Photosensitive Resin Composition A]

| | | |
|---|---|---|
| Cresol-novolac resin “EP4050G” (Asahi Organic | 20 | parts by weight |
| Chemicals Industry) | | |
| Cyclohexanone | 80 | parts by weight |
| Pentaerythritol triacrylate “V#300” (Osaka Organic | 5 | parts by weight |
| Chemical Industry) | | |
| Photopolymerization initiator “Irgacure 369” (Ciba | 1 | part by weight |
| Specialty Chemicals) | | |
| Carbon pigment “MA-8” (Mitsubishi Materials) | 23 | parts by weight |
| Dispersing agent “Solsperse #5000” (ZENECA) | 1.4 | parts by weight |
| Fluorine-containing compound “F179” | 0.5 | part by weight |
| (DAINIPPON INK AND CHEMICALS) | | |

Then, the transparent substrate was pre-baked, followed by an exposure of 100 mJ/cm² with an ultra-high pressure mercury lamp via a photo mask having a lattice-shaped pattern, which was then subjected to development treatment. Further, formed was a bank heated in an oven at a post-baking temperature of 100° C. for 30 minutes (Comparative Example 18). The shape of the bank is shown in Table 4.

For the purpose of checking the shape of the formed bank, the cross-section thereof was observed with a scanning electron microscope. The bank formed in Comparative Example 18 had an inversely tapered shape. The result is shown in Table 4.

Then, the OD value (optical density) of the bank was measured to give 6. Thus, it was confirmed that the bank has sufficient light-shielding properties and it can be employed for the light-shielding layer.

Next, on the substrate having the bank, colored inks were printed with an ink-jet apparatus. The bank formed in Comparative Example 18 dissolved in the colored ink. The result is shown in Table 4.

### Comparative Examples 19 to 23

On the bank (thickness: 1 μm) on the transparent substrate formed in Comparative Example 42, the photosensitive resin composition having the following composition ratio was coated in a thickness of 0.5 μm, 1.0 μm, 2.0 μm, 3.0 μm, or 4.0 μm.

### [Photosensitive Resin Composition A]

| | | |
|---|---|---|
| Cresol-novolac resin “EP4050G”(Asahi Organic | 20 | parts by weight |
| Chemicals Industry) | | |
| Cyclohexane | 80 | parts by weight |
| Pentaerythritol triacrylate “V#300” (Osaka Organic | 5 | parts by weight |
| Chemical Industry) | | |
| Photopolymerization initiator “Irgacure 369” (Ciba | 1 | part by weight |
| Specialty Chemicals) | | |
| Fluorine-containing compound “F179” | 0.5 | part by weight |
| (DAINIPPON INK AND CHEMICALS) | | |

Then, the transparent substrate was pre-baked, followed by an exposure of 100 mJ/cm² with an ultra-high pressure mercury lamp via a photo mask having a lattice-shaped pattern, which was then subjected to development treatment. Subsequently, the transparent substrate was heated in an oven at a post-baking temperature of 100° C. for 30 minutes to form banks (Comparative Examples 19 to 23). The shapes of these banks are shown in Table 4.

For the purpose of checking the shape of the formed bank, the cross-section thereof was observed with a scanning electron microscope. Banks formed in Comparative Examples 19 to 23 had an inversely tapered shape. These results are shown in Table 4. Then, the OD value (optical density) of the banks was measured to give 3. Thus, it was confirmed that the banks have sufficient light-shielding properties and each of these can be employed for the light-shielding layer.

Next, on the substrate having the bank, colored inks were printed with an ink-jet apparatus. Each of banks formed in Comparative Examples 19 to 23 dissolved in the colored ink. These results are shown in Table 4.

TABLE 4

| | | |
|---|---|---|
| [symbol] | [symbol] | [symbol] |
| [symbol] | [symbol] | [symbol] |

| [symbol] | | [symbol] | [symbol] | | [symbol] | [symbol] | | [symbol] | [symbol] |
|---|---|---|---|---|---|---|---|---|---|
| [symbol] | [symbol] | [symbol] | ∘ | [symbol] | [symbol] | ∘ | [symbol] | [symbol] | x |
| [symbol] | [symbol] | [symbol] | ∘ | [symbol] | [symbol] | ∘ | [symbol] | [symbol] | x |
| [symbol] | [symbol] | [symbol] | ∘ | [symbol] | [symbol] | ∘ | [symbol] | [symbol] | x |
| [symbol] | [symbol] | [symbol] | ∘ | [symbol] | [symbol] | ∘ | [symbol] | [symbol] | x |
| [symbol] | [symbol] | [symbol] | ∘ | [symbol] | [symbol] | ∘ | [symbol] | [symbol] | x |
| [symbol] | [symbol] | [symbol] | ∘ | [symbol] | [symbol] | ∘ | [symbol] | [symbol] | x |

[symbol]

indicates data missing or illegible when filed

Hereinafter, Examples and Comparative Examples of forming the bank by a printing method are described.

### Comparative Examples 24 to 31

A resin composition for printing having the following composition ratio was sufficiently kneaded with a three-roller system, which was coated on a transparent substrate in a thickness of 2.0 μm by using a reverse printing method. When carrying out the reverse printing, for a blanket plate, used was a metal roll whose surface was coated with silicone resin. For a peeling member, used was a tabular glass whose surface had been processed to have a convexo-concave pattern corresponding to the reverse pattern for a bank pattern. The ink composition was coated on the blanket plate by using a slit coater to form a uniform ink layer on the blanket plate. Next, from the ink layer on the blanket plate, unnecessary portions were removed by utilizing the peeling member, to form a reverse pattern for the light-shielding layer pattern on the blanket plate. Then, the blanket plate on which the reverse pattern had been formed was abutted on one primary surface of the transparent substrate to transfer the reverse pattern on the surface of the transparent substrate. Thus, a bank was formed on respective transparent substrates.

### [Resin Composition A for Printing]

| | | |
|---|---|---|
| Cresol-novolac resin “EP4050G” (Asahi Organic | 20 | parts by weight |
| Chemicals Industry) | | |
| Cyclohexane | 80 | parts by weight |
| “MX-706” (Sanwa Chemical) | 6 | parts by weight |
| Carbon pigment “MA-8” (Mitsubishi Materials) | 23 | parts by weight |
| Dispersing agent “Solsperse #5000” (ZENECA) | 1.4 | parts by weight |
| Fluorine-containing compound “F179” | 0.5 | part by weight |
| (DAINIPPON INK AND CHEMICALS) | | |

Then, each of the transparent substrate was heated in an oven under temperature conditions as shown in Table 5, 1 to 8 for 30 minutes to form a bank (Comparative Examples 24 to 31 as shown in Table 5).

For the purpose of checking the shape of the formed bank, the cross-section thereof was observed with a scanning electron microscope. Banks formed in Comparative Examples 24 to 27 had an inversely tapered shape. In banks formed in Comparative Examples 28 to 31, heat sagging occurred to give a rounded bowl-like shape. These results are shown in Table 5.

Then, the OD value (optical density) of the banks was measured to give 6. Thus, it was confirmed that the banks have sufficient light-shielding properties and each of these can be employed for the light-shielding layer.

Then, on the substrate having the bank, colored inks were printed with an ink-jet apparatus. Each of banks formed in Comparative Examples 24-27 dissolved in the colored ink. These results are shown in Table 5.

### Examples 37 to 39 and Reference Examples 26 to 30

A resin composition for printing having the following composition ratio was sufficiently kneaded with a three-roller system, which was coated on a transparent substrate in a thickness of 2.0 μm by using a reverse printing method. When carrying out the reverse printing, for a blanket plate, used was a metal roll whose surface was coated with silicone resin. For a peeling member, used was a tabular glass whose surface had been processed to have a convexo-concave pattern corresponding to the reverse pattern for a bank pattern. The ink composition was coated on the blanket plate by using a slit coater to form a uniform ink layer on the blanket plate. Next, from the ink layer on the blanket plate, unnecessary portions were removed by utilizing the peeling member, to form a reverse pattern for the light-shielding layer pattern on the blanket plate. Then, the blanket plate on which the reverse pattern had been formed was abutted on one primary surface of the transparent substrate to transfer the reverse pattern on the surface of the transparent substrate. Thus, a bank was formed on respective transparent substrates.

### [Resin Composition B for Printing]

| | | |
|---|---|---|
| Cresol-novolac resin “EP4050G” (Asahi Organic | 20 | parts by weight |
| Chemicals Industry) | | |
| Melamine resin “MX-706” (Sanwa Chemical) | 6 | parts by weight |
| Cyclohexane | 80 | parts by weight |
| “MX-706” (Sanwa Chemical) | 6 | parts by weight |
| Carbon pigment “MA-8” (Mitsubishi Materials) | 23 | parts by weight |
| Dispersing agent “Solsperse #5000” (ZENECA) | 1.4 | parts by weight |
| Fluorine-containing compound “F179” | 0.5 | part by weight |
| (DAINIPPON INK AND CHEMICALS) | | |

Then, each of the transparent substrates was heated in an oven under temperature conditions as shown in Table 5, 1 to 8 for 30 minutes to form a bank (Examples 37 to 39 and Reference Examples 26 to 30 as shown in Table 5).

For the purpose of checking the shape of the formed bank, the cross-section thereof was observed with a scanning electron microscope. Banks formed in Reference Example 26 and Examples 37-39 had an inversely tapered shape. In banks formed in Reference Examples 27 to 30, heat sagging occurred to give a rounded bowl-like shape. These results are shown in Table 5.

Then, the OD value (optical density) of the banks was measured to give 6. Thus, it was confirmed that the banks have sufficient light-shielding properties and each of these can be employed for the light-shielding layer.

Next, on the substrate having the bank, colored inks were printed with an ink-jet apparatus. The bank formed in Reference Example 26 dissolved in the colored ink. The banks formed in Examples 37-39 and Reference Examples 27 to 30 did not dissolve in the colored ink. In addition, the contact angle between the side surface of the banks formed in Examples 37 to 39 and the colored ink was measured to give around 30 degrees for respective banks. Thus, it was confirmed that they have further ink-repellent properties for the colored ink. These results are shown in Table 5.

TABLE 5

| | | | resin composition A | | | resin composition B | |
|---|---|---|---|---|---|---|---|
| | | | for printing | | | for printing | |
| | temperature | | | chemical | | | chemical |
| condition | (° C.) | | configuration | resistance | | configuration | resistance |
| 1 | 75 | Comparative | [symbol] | x | Reference | [symbol] | x |
| | | Example 24 | | | Example 26 | | |
| 2 | 100 | Comparative | [symbol] | x | Example 37 | [symbol] | ∘ |
| | | Example 25 | | | | | |
| 3 | 112 | Comparative | [symbol] | x | Example 38 | [symbol] | ∘ |
| | | Example 26 | | | | | |
| 4 | 125 | Comparative | [symbol] | x | Example 39 | [symbol] | ∘ |
| | | Example 27 | | | | | |
| 5 | 137 | Comparative | [symbol] | x | Reference | [symbol] | ∘ |
| | | Example 28 | | | Example 27 | | |
| 6 | 150 | Comparative | [symbol] | x | Reference | [symbol] | ∘ |
| | | Example 29 | | | Example 28 | | |
| 7 | 167 | Comparative | [symbol] | x | Reference | [symbol] | ∘ |
| | | Example 30 | | | Example 29 | | |
| 8 | 180 | Comparative | [symbol] | Δ | Reference | [symbol] | ∘ |
| | | Example 31 | | | Example 30 | | |

Hereinafter, described are steps for forming colored pattern layers on the transparent substrate provided with the bank prepared in the above Example with an ink-jet apparatus. In addition, as an example of a substrate with a color pattern, a color filter is described.

<Formation of Substrates with Color Patterns by Using the Bank of the Invention>

### (Preparation of Colored Inks)

### [Colored Ink Composition]

| | | |
|---|---|---|
| Methacrylic acid | 20 | parts by weight |
| Methyl methacrylate | 10 | parts by weight |
| Butyl methacrylate | 55 | parts by weight |
| Hydroxyethyl methacrylate | 15 | parts by weight |
| butyl lactate | 300 | parts by weight |

To a colored ink composition having the above composition, 0.75 part by weight of azobisisobutyronitrile was added under nitrogen atmosphere, which were reacted under conditions of 70° C. for 5 hours to give an acrylic copolymer resin. The obtained acrylic copolymer resin was diluted with propylene glycol monomethyl ether acetate so as to be 10% by weight relative to the whole, to give a diluted liquid of the acrylic copolymer resin.

To 80.1 grams of the diluted liquid, added were 19.0 grams of color pigment and 0.9 gram of polyoxyethylene alkyl ether as a dispersing agent, which was kneaded with a three-roll system to give each of colored varnishes of red, green and blue. Pigment red 177 was used for the red pigment, pigment green 36 was used for the green pigment, and pigment blue 15 was used for the blue pigment.

To the obtained colored varnishes, propylene glycol monomethyl ether acetate was added by a controlled amount so that the pigment concentration of 12 to 15% by weight and the viscosity of 15 cps were resulted in, to give red, green and blue inks.

Specific examples of the color pigment to be added to the colored ink composition include Pigment Red 9, 19, 38, 43, 97, 122, 123, 144, 149, 166, 168, 177, 179, 180, 192, 215, 216, 208, 216, 217, 220, 223, 224, 226, 227, 228, 240, Pigment Blue 15, 15:6, 16, 22, 29, 60, 64, Pigment Green 7, 36, Pigment Red 20, 24, 86, 93, 108, 109, 110, 117, 125, 137, 138, 139, 147, 148, 153, 154, 166, 168, 185, Pigment Orange 36, and Pigment Violet 23. These may be used independently, or in a mixture of two or more types.

For the solvent for use in the colored ink composition, those having a surface tension that lies within such a suitable range for an ink-jet system as, for example, 40 mN/m or lower, and a boiling point of 130° C. or higher can be used preferably. A surface tension exceeding 40 mN/m tends to give a significant adverse effect on the stability of the dot shape at discharging ink-jet, and a boiling point lower than 130° C. tends to result in such failure as nozzle clogging due to significantly too high drying property near the nozzle. Examples of preferred solvents include 2-methoxyethanol, 2-ethoxyethanol, 2-butoxyethanol, 2-ethoxyethyl acetate, 2-butoxyethyl acetate, 2-methoxyethyl acetate, 2-ethoxyethyl ether, 2-(2-ethoxyethoxy)ethanol, 2-(2-butoxyethoxy)ethanol, 2-(2-ethoxyethoxy)ethyl acetate, 2-(2-butoxyethoxy)ethyl acetate, 2-phenoxyethanol, and diethylene glycol dimethyl ether. They may be used independently, or in a mixture of two or more type, according to need. For the solvent, in addition to dissolving power, temporal stability, drying property etc. are required, and a solvent is suitably selected according to the property of a colorant and a binder resin to be used.

To the colored ink composition, an under-mentioned binder resin can be blended. Examples of the binder resin for the colored ink composition include casein, gelatin, polyvinyl alcohol, carboxymethyl acetal, polyimide resin, acrylic resin, epoxy resin, and melamine resin. They may be suitably selected according to a colorant to be used. For example, in case where heat resistance or light resistance is required, an acrylic resin is preferred.

In order to improve the dispersion of the pigment into the binder resin of the colored ink composition, it is possible to add a dispersing agent to the ink for coating the colored pattern. Examples of the dispersing agent include such nonionic surfactant as polyoxyethylene alkyl ether, such ionic surfactants as sodium alkylbenzene sulfonate, polyfatty acid salt, fatty acid salt alkyl phosphate and tetraalkylammonium salt, and, in addition, organic pigment derivatives and polyester. The dispersing agent may be used independently, or in a mixture of two or more types.

The height of colored layers of respective colors can be controlled according to the height of the bank etc., and they may be formed in a thickness of, for example, from 1 μm to 2 μm.

As the colored ink, an ink for a color filter is described. The colored ink can be used for an ink for an electroluminescence element in a case where an organic electroluminescence material is used instead of a colored pigment and an ink includes the above-mentioned solvents or additives according to need. As a colored layer, an electroluminescence layer can be formed by using this ink.

(Formation of Substrates with Color Patterns)

For the transparent substrate having the bank formed in Examples 1 to 39, respective colored layers of red (R), green (G) and blue (B) were formed by using the red, green and blue colored inks with an ink-jet apparatus mounted with a 12 pl, 180 dpi head.

The substrates with color patterns thus obtained have good flatness, and, when ΔEab in respective pixels was measured, it was less than 1 for all of them to show that the substrates with color patterns were good one having a little color unevenness. The ΔEab (color difference) was measured with a micro analyzer.

Further, when verifying presence or absence of color mixture of the colored ink due to an ink-jet for substrates with color patterns having the bank formed in Examples 31 to 36, the results as shown in Table 6 were obtained.

TABLE 6

photosensitive resin composition B
(post-baking temperature: 100° C.)

| | | | | color |
|---|---|---|---|---|
| thickness | | | configuration | mixture |
| 1.0 | μm | Example 31 | [symbol] | X |
| 1.5 | μm | Example 32 | [symbol] | Δ |
| 2.0 | μm | Example 33 | [symbol] | ◯ |
| 3.0 | μm | Example 34 | [symbol] | ⊚ |
| 4.0 | μm | Example 35 | [symbol] | ⊚ |
| 5.0 | μm | Example 36 | [symbol] | ⊚ |

⊚: no color mixture, ◯: little color mixture,
Δcolor mixture occorred a little, X: color mixture occurred.

(This application is incorporated by reference which is Japanese application number 2005-091479, which is filed on Mar. 28, 2005.)

What is claimed is:

1. A substrate with a bank, comprising:
a substrate; and
a bank on the substrate, wherein:
the bank comprises a resin composition containing at least a binder resin, and melamine resin or a derivative thereof; and
the amount of the melamine resin or derivative thereof is from 5 to 30 parts by weight relative to 100 parts by weight of the binder resin.

2. The substrate with a bank according to claim 1, wherein a part or the whole of the bank is black.

3. The substrate with a bank according to claim 1, wherein the bank has ink-repellent properties.

4. The substrate with a bank according to claim 1, wherein the resin composition forming the bank includes a fluorine-containing compound.

5. The substrate with a bank according to claim 1, wherein the height of the bank is within a range from 1.5 μm to 5 μm.

6. The substrate with a bank according to claim 1, wherein the bank has one layer and is formed by means of a photolithographic method.

7. The substrate with a bank according to claim 1, wherein the bank has one layer and is formed by means of a printing method.

8. A substrate with a color pattern comprising:
a substrate;
banks on the substrate; and
a colored layer arranged between the banks, wherein:
the banks comprise a resin composition containing at least a binder resin, and melamine resin or a derivative thereof;
the amount of the melamine resin or derivative thereof is from 5 to 30 parts by weight relative to 100 parts by weight of the binder resin; and
the colored layer is formed by means of an ink-jet system while using a colored ink.

9. The substrate with the color pattern according to claim 8, wherein the bank does not dissolve in the colored ink.

10. The substrate with the color pattern according to claim 8, wherein a part or the whole of the bank is black.

11. The substrate with the color pattern according to claim 8, wherein the bank has ink-repellent properties.

12. The substrate with the color pattern according to claim 8, wherein the resin composition forming the bank includes a fluorine-containing compound.

13. The substrate with the color pattern according to claim 8, wherein the height of the bank is within a range from 1.5 μm to 5 μm.
